(19) United States
(12) Patent Application Publication
(10) Pub. No.: US 2026/0362582 A1
(43) Pub. Date: Nov. 12, 2026

(54) Connection Element Between a Heat-Emitting Electrical Component and a Heat Sink, and Electrical Circuit Board Comprising Such a Connection Element

(71) Applicant: BRUSA ELEKTRONIK AG, Buchs (CH)

(72) Inventors: Marc Hanselmann, Buchs (CH); Martin Erler, Buchs (CH); Patrick Buechel, Buchs (CH); Namita Vyas, Buchs (CH)

(21) Appl. No.: 19/514,989

(22) PCT Filed: Sep. 26, 2024
(86) PCT No.: PCT/EP2024/077046

§ 371 Date: Feb. 27, 2026

(30) Foreign Application Priority Data
Oct. 2, 2023 (DE) 10 2023 126 832.5

(51) Int. Cl. H05K 1/02; B60L 53/12; B60L 53/302; H02J 50/00; H02J 50/10

(52) U.S. Cl. CPC H05K 1/0203; B60L 53/12; B60L 53/302; H02J 50/005; H02J 50/10; H05K 2201/066

(57) ABSTRACT

A connection element between a heat-emitting electrical component and a heat sink, wherein the connection element is constructed in layers from at least three material layers, wherein a first material layer consists of a thermally conductive and electrically insulating first material and has a contact surface for the thermally conductive arrangement of the heat-emitting electrical component, a third material layer which consists of a thermally conductive third material and has a contact surface for thermally conductive contact with the heat sink, and a second material layer consisting of a thermally conductive and electrically conductive second material arranged between the first material layer and the third material layer,

### CROSS REFERENCE TO RELATED APPLICATIONS

The present application is the U.S. National Phase of PCT/EP2024/077046, filed on 26 Sep. 2024, which claims priority to German Patent Application No. 10 2023 126 832.5, filed on 2 Oct. 2023, the entire contents of which are incorporated herein by reference.

### BACKGROUND

### Field

The invention relates to a connection element between a heat-emitting electrical component and a heat sink, an electrical circuit board comprising such a connection element, a ground pad module (GPM) or a car pad module (CPM) of an inductive charging system with such a connection element, and an inductive vehicle charging system with such a ground pad module (GPM) or a car pad module (CPM).

### Related Art

In power electronics components, such as power semiconductors or corresponding power electronics assemblies, significant amounts of heat are generated in part during operation, which must be dissipated to prevent overheating or even destruction of these components or assemblies. Typically, the heat-emitting components are thermally coupled to a heat sink, usually via a thermally conductive and electrically non-conductive interface material.

However, this thermal coupling of an electronic component of a power electronics assembly with a heat sink creates a parasitic capacitance through the interface material, for example, between a surface of a power semiconductor to be cooled and the heat sink thermally coupled via the interface material, which leads to undesirable stray currents and thus to undesirable feedback effects on the power electronics circuit, especially during electrical switching operations in the electronic component or in the power electronics assembly.

Power electronic components, so-called SMD components (surface-mounted device), which are arranged directly on an electrical circuit board (PCB), thus also require effective cooling to remove heat generated during operation, often also through the circuit board PCB to a heat sink thermally coupled below the circuit board. Heat conduction through the circuit board (PCB) can be achieved, for example, by heat conduction channels made of a highly thermally conductive material arranged in the electrical circuit board PCB and its thermal coupling to the heat sink. Here too, in the prior art, the thermal coupling of such heat conduction channels of electrical circuit boards PCBs to a heat sink typically occurs via a thermally conductive and electrically non-conductive interface material, with the aforementioned undesirable effects.

### SUMMARY

The object of the invention is to provide a connection element between a heat-emitting electrical component and a heat sink in which the aforementioned parasitic capacitances no longer occur or only occur in a greatly reduced form.

The invention results from the features of the independent claims. Advantageous refinements and embodiments are the subject matter of the dependent claims. Other features, possible applications, and advantages of the invention will be apparent from the following description and from the discussion of example embodiments of the invention, which are depicted in the figures.

A first aspect of the invention relates to a connection element between a heat-emitting electrical component and a heat sink. The connection element is characterized by the fact that the connection element is constructed in layers from at least three material layers, wherein a first material layer consists of a thermally conductive and electrically insulating first material and has a contact surface for the thermally conductive arrangement of the heat-emitting electrical component, a third material layer consisting of a thermally conductive third material and has a contact surface for thermally conductive contact with the heat sink, and a second material layer consisting of a thermally conductive and electrically conductive second material is arranged between the first material layer and the third material layer.

These three material layers are advantageously designed to be flat and arranged one above the other. Advantageously, the third material layer is arranged directly adjacent to the second material layer (contacting it) and/or the second material layer is arranged directly adjacent to the first material layer (contacting it). Advantageously, the heat-emitting electrical component is located directly at the contact surface of the first material layer and the heat sink is located directly at the third material layer.

The term “component” can here refer to a single electrical component (e.g., a power transistor) or a group of multiple electrical components that together form a heat-emitting electrical component.

In this case, an electrical component can also be an electrical assembly. In this context, the term “heat sink” refers to a passive and/or active heat sink.

The heat-emitting electrical component can be surrounded by a housing. In this case, the housing, as the outer heat-emitting contact surface of the electrical component, can contact the first material layer.

The first material layer acts as a non-electrically conductive dielectric between the electrical component and the electrically conductive second material layer. This initially creates a parasitic capacitance between the electrical component and the electrically conductive second material layer. The same applies to the third material layer. It acts as a non-electrically conductive dielectric between the electrically conductive second material layer and the heat sink. This initially creates a parasitic capacitance between the conductive second material layer and the heat sink.

The second material layer is particularly advantageous during operation of the electrically heat-emitting component, as it is kept constant at a predetermined electrical potential. This potential can advantageously be a static potential, such as the electrical potential of the earth, or a positive or negative potential. The latter is advantageously a positive or negative potential of an associated direct current intermediate circuit or a midpoint potential of an associated direct current intermediate circuit.

The electrically constantly kept potential of the second material layer ensures that, during operation of the heat-emitting component, especially during electrical switching processes (transient electrical states) in the component, the parasitic capacitance between the second material layer and the heat sink is neither charged nor discharged. During transient electrical states in the heat-emitting component, only the parasitic capacitance between the electrical component and the second material layer is charged or discharged. Stray currents, as described above in the prior art, are thereby significantly reduced.

Depending on how the electrically constant potential is chosen, the insulation requirements can be reduced (e.g., a midpoint potential of the direct current link is an advantageous option here).

In a further development of the proposed connection element, the third material is electrically insulating. In a further development of the proposed connection element, the third material is electrically conductive.

In an advantageous further development of the connection element, the second material layer or the second and the first material layer or the third and the second and the first material layer are arranged within an electrical circuit board (PCB). This enables, in particular, effective cooling of SMD components on electrical circuit boards with significantly reduced stray currents generated by parasitic capacitances.

In an advantageous development of the connection element, the third material layer is arranged directly adjacent to the second material layer and/or the second material layer is arranged directly adjacent to the first material layer. This means that the respective material layers are advantageously coupled directly to each other mechanically, electrically and thermally.

Advantageously, the connection element comprises exactly the first, second, and third material layers.

Advantageously, the first material consists of
FR4,
ceramics,
aluminum oxide and/or aluminum oxide substrates,
aluminum nitride and/or aluminum nitride substrates,
silicon nitride and/or silicon nitride substrates,
Zircon-doped Al₂O₃ substrates,
glass fiber reinforced plastic material,
polyamide,
or a mixture thereof.

Advantageously, the second material consists of
copper,
aluminum,
silver,
gold,
metal alloys with good electrical conductivity,
or a mixture thereof.

Advantageously, the third material consists of
FR4,
ceramics,
aluminum oxide and/or aluminum oxide substrates,
aluminum nitride and/or aluminum nitride substrates,
silicon nitride and/or silicon nitride substrates,
Zircon-doped Al₂O₃ substrates,
glass fiber reinforced plastic material,
polyamide,
a thermal paste,
solder,
or a mixture thereof.

Another aspect of the invention relates to a ground module GPM or vehicle module CPM for an inductive vehicle charging system, wherein energy can be inductively transferred from a ground module GPM to a vehicle module CPM arranged in a vehicle and vice versa, and wherein the ground module GPM or the vehicle module CPM has at least one electrical component that emits heat during operation. The proposed ground module GPM or the proposed vehicle module CPM is characterized by the fact that this heat-emitting component is connected to a heat sink via a connection element, as described above.

The heat-emitting component is advantageously part of a power electronics circuit.

Advantages and preferred developments of the proposed ground module GPM or proposed vehicle module CPM result from an analogous and corresponding transfer of the statements made above.

A further aspect of the invention relates to a vehicle comprising a vehicle module CPM as described above.

A further aspect of the invention relates to an inductive vehicle charging system comprising a ground module GPM and/or a vehicle module CPM, as previously described.

Another aspect of the invention relates to an electrical circuit board (PCB) comprising at least one connection element, as described above.

The electrical circuit board (PCB) is advantageously flexible.

Further advantages, features, and details will be apparent from the following description, in which—optionally with reference to the drawing—at least one example embodiment is described in detail. Identical, similar, and/or functionally identical parts are provided with the same reference numerals,

### BRIEF DESCRIPTION OF THE DRAWINGS

In the drawings:

FIG. 1 shows a highly schematic representation of a connection element.

### DETAILED DESCRIPTION

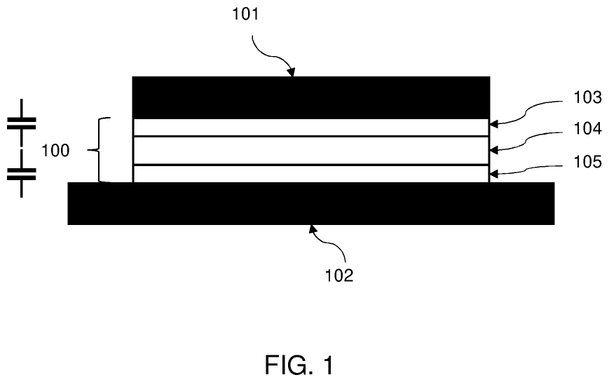

FIG. 1 shows a highly schematic representation of a connection element 100, which is arranged between a heat-emitting electrical component 101, e.g., a power semiconductor and a heat sink 102. The connection element 100 is constructed in layers from three material layers, wherein a first material layer 103 consists of a thermally conductive and electrically insulating first material, e.g., FR4, and has a contact surface for the heat-conducting arrangement of the heat-emitting electrical component 101.

A third material layer 105 consists of a thermally conductive third material, e.g., a zirconium-doped Al₂O₃ substrate (DCB: English for “direct copper bond”) and has a contact surface for thermally conductive contact with the heat sink 102.

Between the first material layer 103 and the third material layer 105, a second material layer 104 is arranged, which consists of a thermally conductive and electrically conductive second material, e.g., copper.

The second material layer 104 is kept constant, during operation of the electrical component 101, at a predetermined electrical potential.

Although the invention has been further illustrated and described in detail by way of preferred example embodiments, the invention is not limited by the disclosed examples, and other variations can be derived therefrom by a person skilled in the art without departing from the scope of the invention. It is therefore clear that a variety of possible variations exists. It is also clear that exemplified embodiments are really only examples, which are not to be construed in any way as limiting the scope, applicability, or configuration of the invention. Rather, the foregoing description and description of the figures enable a person skilled in the art to implement the example embodiments, and such person may make various changes knowing the disclosed inventive concept, for example with respect to the function or arrangement of individual elements cited in an example embodiment, without departing from the scope as defined by the claims and their legal equivalents, such as a more extensive explanation in the description.

### LIST OF REFERENCE NUMERALS

100 connection element
101 heat-emitting electrical component/assembly
102 heat sink
103 first material layer
104 second material layer
105 third material layer

1. A connection element between a heat-emitting electrical component and a heat sink, wherein the connection element is constructed in layers from at least three material layers, wherein a first material layer consists of a thermally conductive and electrically insulating first material and has a contact surface for thermally conductive arrangement of the heat-emitting electrical component, a third material layer consisting of a thermally conductive third material and having a contact surface for thermally conductive contacting with the heat sink, and a second material layer consisting of a thermally conductive and electrically conductive second material arranged between the first material layer and the third material layer.

2. The connection element according to claim 1, wherein the second material layer is kept during operation constant at a predetermined electrical potential.

3. The connection element according to claim 1, wherein the third material is electrically insulating.

4. The connection element according to claim 1, wherein the third material is electrically conductive.

5. The connection element according to claim 1, wherein the second material layer, or the second material layer and the first material layer, or the third material layer and the second material layer and the first material layer are arranged within an electrical circuit board (PCB).

6. The connection element according to claim 1, wherein the third material layer is arranged directly on the second material layer and/or the second material layer is arranged directly on the first material layer.

7. The connection element according to claim 1, wherein the connection element comprises exactly the first material layer, the second material layer, and the third material layer.

8. The connection element according to claim 1, wherein the first material is selected from
FR4.
ceramics,
aluminum oxide and substrates,
aluminum nitride and substrates,
Silicon nitrite and substrates,
Zircon-doped Al₂O₃ substrates,
glass fiber reinforced plastic material,
polyamide, or
a mixture thereof.

9. The connection element according to claim 1, wherein the second material is selected from
copper,
aluminum,
silver,
gold,
metal alloys with good electrical conductivity, or
a mixture thereof,

10. The connection element according to claim 1, wherein the third material is selected from
FR4,
ceramics,
aluminum oxide and substrates,
aluminum nitride and substrates.
silicon nitrite and substrates,
Zircon-doped Al₂O₃ substrates,
glass fiber reinforced plastic material,
polyamide.
a thermal paste,
solder, or
a mixture thereof.

11. A ground module (GPM) or vehicle module (CPM) for an inductive vehicle charging system, wherein energy is capable of being inductively transferred from the ground module (GPM) to the vehicle module (CPM) arranged in a vehicle and vice versa, and wherein the ground module (GPM) or the vehicle module (CPM) has at least one electrical component that emits heat during operation, wherein this heat-emitting component is connected to a heat sink via a connection element according to claim 1.

12. The ground module (GPM) and/or vehicle module (CPM) according to claim 11, wherein the heat-emitting component is part of a power electronics circuit.

13. An inductive vehicle charging system comprising a ground module (GPM) and/or vehicle module (CPM) according to claim 11.

14. An electrical circuit board PCB comprising at least one connection element according to claim 1.
